(19) United States
(12) Patent Application Publication
(10) Pub. No.: US 2009/0053478 A1
(43) Pub. Date: Feb. 26, 2009

(54) FUNCTIONAL FILM CONTAINING STRUCTURE AND METHOD OF MANUFACTURING FUNCTIONAL FILM

(75) Inventor: Yukio Sakashita, Kaisei-machi (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Minato-ku, Tokyo (JP)

(21) Appl. No.: 11/817,363

(22) PCT Filed: Jun. 5, 2006
(86) PCT No.: PCT/JP2006/311669

§ 371 Date: Aug. 29, 2007

(30) Foreign Application Priority Data
Jun. 7, 2005 (JP) 2005-166405

(51) Int. Cl. C23C 14/00; B32B 9/00; B32B 17/06; B32B 3/10; H01L 21/00; B05D 3/06; B44C 1/22

(52) U.S. Cl. 428/195.1; 428/698; 428/702; 428/426; 428/432; 427/532; 427/553; 216/37; 438/463; 257/E21.001

(57) ABSTRACT

A method of manufacturing a functional film by which a functional film formed on a film formation substrate can be easily peeled from the film formation substrate. The method includes the steps of: (a) forming an electromagnetic wave absorbing layer on a substrate by using a material which absorbs an electromagnetic wave to generate heat; (b) forming a separation layer on the electromagnetic wave absorbing layer by using an inorganic material which is decomposed to generate a gas by being heated; (c) forming a layer to be peeled containing a functional film; and (d) applying the electromagnetic wave toward the electromagnetic wave absorbing layer so as to peel the layer to be peeled from the substrate or reduce bonding strength between the layer to be peeled and the substrate.

### TECHNICAL FIELD

The present invention relates to a method of manufacturing a functional film including a dielectric material, piezoelectric material, pyroelectric material, magnetic material, semiconductor material or the like, and a functional film containing structure to be used in a manufacturing process of the functional film.

### BACKGROUND ART

Recent years, in response to the needs for electronic devices such as miniaturization, speeding up, integration, and multifunctionality, the manufacture of devices containing functional materials such as electronic ceramics, which express predetermined functions by being applied with electric fields or magnetic fields and include a dielectric material, piezoelectric material, magnetic material, pyroelectric material and semiconductor material, by using various film formation technologies has been actively studied.

For example, in order to enable high-definition and high-quality printing in an inkjet printer, it is necessary to miniaturize and highly integrate ink nozzles of inkjet heads. Accordingly, it is also necessary to similarly miniaturize and highly integrate piezoelectric actuators for driving the respective ink nozzles. In such a case, a film formation technology, that enables formation of a thinner layer than a bulk material and formation of fine patterns, is desired, and film formation technologies such as a sputtering method, a sol-gel method, and an aerosol deposition method have been studied.

However, there has been a problem that a film of function material (also simply referred to as “functional film”) formed by film formation does not sufficiently exert its function in a condition after the film formation, and the film is inferior to a bulk material in performance.

In order to sufficiently express the function of a functional film, heat treatment at relatively high temperature (e.g., about 500° C. to 1000° C.) is required after film formation. Since a substrate that is used at the time of film formation (film formation substrate) is simultaneously heat-treated, high heat tolerance is required for the material of film formation substrate. On the other hand, in the case where a fabricated function film is utilized, there is demand for using various kinds of substrates according to instruments such as a flexibly substrate made of resin, for example. Accordingly, a method has been studied by which a functional film formed on a film formation substrate can be peeled or transferred from the film formation substrate without hindering its function.

As a related technology, Japanese Patent Application Publication JP-A-54-94905 discloses a multilayered structure for thin film transfer having a heat-resistant substrate, a release layer principally containing carbon and/or carbon compound, and a functional thin film as main component elements (page 1). Further, JP-A-54-94905 discloses that the functional thin film can be peeled from the heat-resistant substrate and transferred to another substrate because the release layer can be removed by oxidization (combustion) (page 3).

Japanese Patent Application Publication JP-A-10-125929 discloses a peeling method by which any material to be peeled can be easily peeled regardless of its properties and conditions, and especially, the peeled material can be transferred to various transfer materials. The peeling method is to peel a material to be peeled existing on a substrate via a separation layer having a multilayered structure of plural layers from the substrate, and includes the steps of applying irradiating light to the separation layer to cause peeling within the layer of the separation layer and/or at an interface thereof so as to detach the material to be peeled from the substrate (pages 1 and 2). Further, in JP-A-10-125929, as the composition of a light absorption layer, amorphous silicon, silicon oxide, dielectric material, nitride ceramics, organic polymer and so on are cited (pages 5 and 6).

Japanese Patent Application Publication JP-P2004-165679A discloses a method of transferring a thin film device, which method is for matching (i) a multilayer relationship of the layer to be transferred against a substrate used when the layer to be transferred is manufactured and (ii) a multilayer relationship of the layer to be transferred against a transfer material as a transfer destination of the layer to be transferred. The method includes the first step of forming a first separation layer on a substrate, the second step of forming a layer to be transferred containing a thin film device on the first separation layer, the third step of forming a second separation layer consisting of a water-soluble or organic solvent-soluble adhesive agent on the layer to be transferred, the fourth step of bonding a primary transfer material onto the second separation layer, the fifth step of removing the substrate from a material to be transferred by using the first separation layer as a boundary, the sixth step of bonding a secondary transfer material to an undersurface of the layer to be transferred, and the seventh step of bringing the second separation layer into contact with water or organic solvent to remove the primary transfer material from the transfer layer by using the second separation layer as a boundary (pages 1 and 2). Further, in JP-P2004-165679A, as the composition of the separation layer, amorphous silicon, silicon oxide, dielectric material, nitride ceramics, organic polymer and so on are cited (pages 8 and 9).

However, according to JP-A-54-94905, since the release layer is removed by oxidation reaction, the atmosphere in the heat treatment process is limited to an oxygen atmosphere. Further, since carbon or carbon compound is used as the release layer, there is the upper limit to heating temperature. For example, in an embodiment disclosed in JP-A-54-94905 (pages 1 and 3), the treatment temperature in the transfer process is 630° C. at the highest. Therefore, the invention disclosed in JP-A-54-94905 cannot be applied to a manufacture of electronic ceramics that requires heat treatment at relatively high temperature (e.g., 700° C. or more).

According to JP-A-10-125929, peeling is caused within the separation layer or at the interface by applying a laser beam to a light absorption layer contained in the separation layer to allow the light absorption layer to ablate. That is, a solid material contained in the light absorption layer is photochemically or thermally excited by absorbing applied light, and thereby, bonding between atoms or molecules of the surface or inside thereof is cut and they are released. As a result, a phase change such as melting or transpiration (vaporization) occurs in the constituent material of the light absorption layer, and the material to be peeled is peeled at relatively low temperature. However, according to the method, the peeling property is likely to be insufficient. Further, JP-A-10-125929 does not disclose that a chemical change such as reaction with other component or decomposition is made in a constituent material of the light absorption layer.

On the other hand, according to JP-P2004-165679A, when the thin film device is detached from the substrate by applying a laser beam to the separation layer, in order to peel the thin film device from the substrate more reliably, ions for promoting peeling are implanted into the separation layer. According to such a method, inner pressure is generated in the separation layer and the peeling phenomenon is promoted. However, since hydrogen ions cited as ions for promoting peeling in JP-P2004-165679A are gasified at 350° C. or more and exit from the separation layer (page 6), the process temperature after ion implantation can not be set to 350° C. or more.

### DISCLOSURE OF THE INVENTION

In view of the above-mentioned problems, a first purpose of the present invention is to provide a method of manufacturing a functional film by which a functional film formed on a film formation substrate can be easily peeled from the film formation substrate. Further, a second purpose of the present invention is to provide a functional film containing structure to be used in a manufacturing process of such a functional film.

In order to accomplish the purposes, a functional film containing structure according to a first aspect of the present invention includes: a substrate; an electromagnetic wave absorbing layer provided on the substrate and formed by using a material which absorbs an electromagnetic wave to generate heat; a separation layer provided on the electromagnetic wave absorbing layer and formed by using an inorganic material which is decomposed to generate a gas by being heated; and a layer to be peeled provided on the separation layer and containing a functional film formed by using a functional material, and the layer to be peeled is peeled from the substrate or bonding strength between the layer to be peeled and the substrate becomes lower by applying the electromagnetic wave toward the electromagnetic wave absorbing layer.

A functional film containing structure according to a second aspect of the present invention includes: a substrate; an electromagnetic wave absorbing layer provided on the substrate and formed by using a material which absorbs an electromagnetic wave to generate heat; a separation layer provided on the electromagnetic wave absorbing layer and formed by using an inorganic material which reacts with a component in an atmosphere and/or a component contained in an adjacent layer to generate a gas by being heated; and a layer to be peeled provided on the separation layer and containing a functional film formed by using a functional material, and the layer to be peeled is peeled from the substrate or bonding strength between the layer to be peeled and the substrate becomes lower by applying the electromagnetic wave toward the electromagnetic wave absorbing layer.

Further, a method of manufacturing a functional film according to a first aspect of the present invention includes the steps of: (a) forming an electromagnetic wave absorbing layer on a substrate by using a material which absorbs an electromagnetic wave to generate heat; (b) forming a separation layer on the electromagnetic wave absorbing layer by using an inorganic material which is decomposed to generate a gas by being heated; (c) forming a layer to be peeled containing a functional film, which is formed by using a functional material, on the separation layer; and (d) applying the electromagnetic wave toward the electromagnetic wave absorbing layer so as to peel the layer to be peeled from the substrate (101) or reduce bonding strength between the layer to be peeled and the substrate.

A method of manufacturing a functional film according to a second aspect of the present invention includes the steps of: (a) forming an electromagnetic wave absorbing layer on a substrate by using a material which absorbs an electromagnetic wave to generate heat; (b) forming a separation layer on the electromagnetic wave absorbing layer by using an inorganic material which reacts with a component in an atmosphere and/or a component contained in an adjacent layer to generate a gas by being heated; (c) forming a layer to be peeled containing a functional film, which is formed by using a functional material, on the separation layer; and (d) applying the electromagnetic wave toward the electromagnetic wave absorbing layer so as to peel the layer to be peeled from the substrate or reduce bonding strength between the layer to be peeled and the substrate.

Here, “reaction” refers to a process in which, from one material or material system, another material or material system different from the initial material or material system in composition or structure is produced. And “reaction” includes a process in which one kind of compound changes into two or more kinds of simpler materials, and a process in which, based on two kinds of materials including at least one kind of compound, two or more kinds of materials different from the initial materials are produced. Further, the former case is specifically referred to as “decomposition”, and the decomposition brought about by heating is referred to as “thermal decomposition”.

According to the present invention, the electromagnetic wave absorbing layer which absorbs an electromagnetic wave to generate heat and the separation layer which generates gas by being heated are provided between the substrate and the layer to be peeled containing the functional film, and therefore, the functional film can be easily peeled from the substrate by applying the electromagnetic wave toward the electromagnetic wave absorbing layer without heating the entire structure. Alternatively, by reducing the bonding strength between them, the functional film can be dynamically and easily peeled from the substrate at the subsequent step. Accordingly, the functional film formed on the substrate by using a film formation technology can be easily transferred to a flexible substrate or the like having relatively low heat tolerance and utilized. Therefore, elements having advantageous properties can be suitably mounted according to application and the performance of the entire instruments utilizing such elements can be improved.

### BRIEF DESCRIPTION OF THE DRAWINGS

Advantages and features of the present invention will be apparent by considering the following detailed description and the drawings in relation. In these drawings, the same reference numerals indicate the same component elements.

FIG. 1 is a flowchart showing a method of manufacturing a functional film according to the first embodiment of the present invention.

FIGS. 2A to 2D are sectional views for explanation of the method of manufacturing a functional film according to the first embodiment of the present invention.

FIGS. 3A and 3B are sectional views for explanation of the method of manufacturing a functional film according to the first embodiment of the present invention.

FIG. 4 is a sectional view showing a functional film transferred to a substrate for transfer.

FIG. 5 is a sectional view showing a modified example of a functional film containing structure.

FIG. 6 is a sectional view showing another modified example of the functional film containing structure.

FIGS. 7A to 7D are diagrams for explanation of the method of manufacturing a functional film according to the second embodiment of the present invention.

### BEST MODE FOR CARRYING OUT THE INVENTION

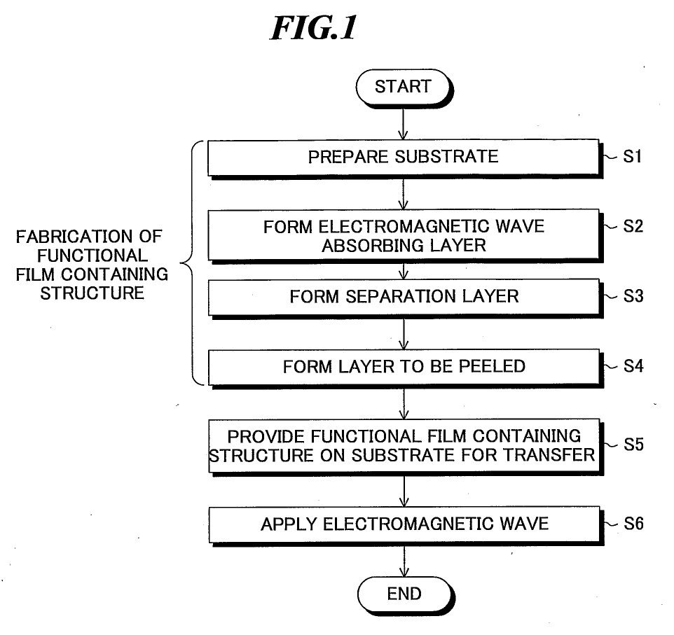

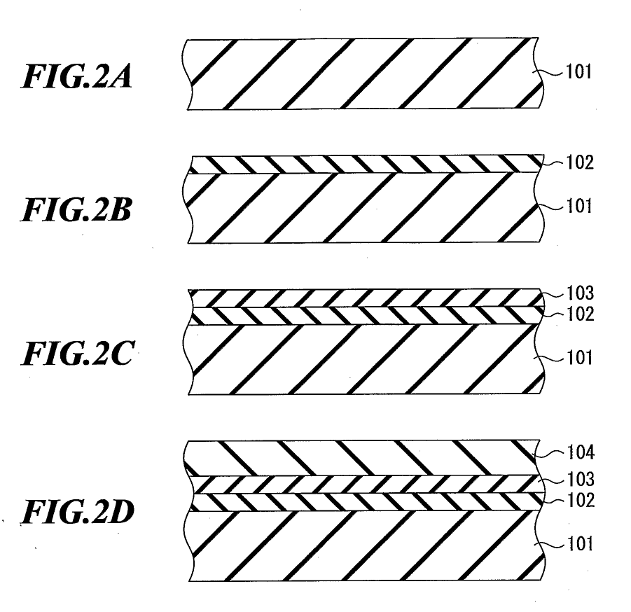

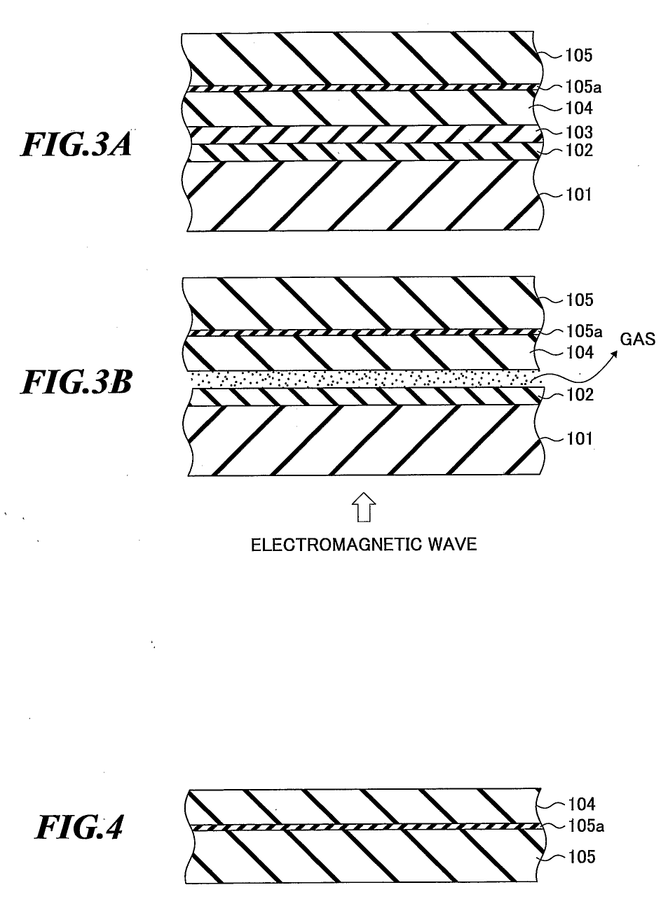

FIG. 1 is a flowchart showing a method of manufacturing a functional film according to the first embodiment of the present invention. Further, FIGS. 2A to 3B are diagrams for explanation of the method of manufacturing a functional film according to the first embodiment of the present invention, in which FIGS. 2A to 2D show steps of fabricating a functional film containing structure according to the first embodiment of the present invention.

First, at step S1 in FIG. 1, a substrate 101 is prepared as shown in FIG. 2A. The substrate 101 is a substrate for film formation to be used in the manufacturing process of the functional film. As the substrate 101, suitable one is selected from among a single crystal substrate including a semiconductor single crystal substrate and an oxide single crystal substrate, a ceramic substrate and a glass substrate according to the wavelength of an electromagnetic wave to be used and so on. For example, in the case where the wavelength of the electromagnetic wave to be used at the subsequent step is relatively short (e.g., ultraviolet rays), it is desired that a substrate through which the electromagnetic wave is propagated or transmitted is used. Further, it is also necessary to select a substrate having heat tolerance to the process temperature at the subsequent step, for example, the film formation temperature when the functional film is formed or the heat treatment is performed according to need.

As an oxide single crystal substrate material, specifically, magnesium oxide (MgO), alumina (Al₂O₃), titanium oxide (TiO₂), zinc oxide (ZnO), spinel (magnesium aluminate, MgAl₂O₄), strontium titanate (SrTiO₃), lanthanum aluminate (LaAlO₃), lithium niobate (LiNbO₃), lithium tantalate (LiTaO₃) and so on are cited. In the case where the oxide single crystal substrate is used, by selecting a material having a predetermined lattice constant according to a functional film as a target of manufacturing, the functional film can be formed by epitaxial growth. Further, since these substrates are stable in an oxidizing atmosphere, they can be used for film formation or heat-treated at high temperature (e.g., about 1000° C. for magnesium oxide) in the air atmosphere.

As a semiconductor single crystal substrate material, specifically, silicon (Si), germanium (Ge), gallium arsenide (GaAs), gallium phosphide (GaP), indium phosphide (InP) and so on are cited. In the case where the semiconductor single crystal substrate is used, by selecting a material having a predetermined lattice constant according to a functional film as a target of manufacturing, the functional film can be formed by epitaxial growth. Further, since these substrates are stable in a reducing atmosphere, they can be used for film formation or heat-treated at high temperature (e.g., about 1000° C. for silicon) in the reducing atmosphere.

As a ceramic substrate material, alumina (Al₂O₃) zirconia (ZrO₂), aluminum nitride (AlN) and so on are cited. Since the ceramic substrate is more inexpensive than the single crystal substrate, the cost of manufacturing can be reduced. Further, since these substrates are stable in the air atmosphere and have high heat tolerance, they can be used for film formation or heat-treated at high temperature (e.g., about 1100° C. for alumina) in the air atmosphere.

As a glass substrate material, specifically, silicate glass, alkaline silicate glass, borosilicate glass, soda-lime glass, lead glass and so on are cited. Since the glass substrate is more inexpensive than the single crystal substrate, 1 the cost of manufacturing can be reduced. Further, since these substrates are stable in an oxidizing atmosphere, they can be used for film formation or heat-treated at high temperature (e.g., about 900° C. for silicate glass) in the air atmosphere.

Then, at step S2, an electromagnetic wave absorbing layer 102 is formed on the substrate 101, as shown in FIG. 2B. The electromagnetic wave absorbing layer 102 is a layer that absorbs, when an electromagnetic wave having a predetermined wavelength is applied, the electromagnetic energy thereof to generate heat. Specifically, it is formed by carbon, ceramics, glass or the like. The material of the electromagnetic wave absorbing layer 102 is desirably determined according to an electromagnetic wave to be used in the subsequent step (an electric wave including a microwave, an infrared ray and so on). Here, the microwave is an electromagnetic wave having a wavelength of about 1 m to 1 mm, and includes UHF wave (decimeter wave), SHF wave (centimeter wave), EHF wave (millimeter wave) and submillimeter wave.

Next, at step S3, a separation layer 103 is formed on the electromagnetic wave absorbing layer 102, as shown in FIG. 2C. The separation layer 103 is a sacrifice layer that is removed when a functional film to be formed at the subsequent step is peeled from the substrate 101. As a material of the separation layer 103, a material is used that induces a reaction of thermal decomposition or the like to generate a gas by being heated. Further, in consideration of process temperature at the subsequent steps such as the film formation temperature when the functional film is formed, it is desired that the material has heat tolerance to about 350° C. or more.

Specifically, a compound containing at least one of carbonates of magnesium carbonate (MgCO₃, decomposed at about 600° C.), calcium carbonate (CaCO₃, decomposed at about 900° C.), strontium carbonate (SrCO₃, decomposed at about 900° C.), barium carbonate (BaCO₃, decomposed at about 1450° C.), lithium carbonate (LiCO₃, decomposed at about 618° C.), sodium carbonate (Na₂CO₃), potassium carbonate (K₂CO₃) and so on, a compound containing at least one of sulfates of magnesium sulfate (MgSO₄, decomposed at about 1185° C.), calcium sulfate (CaSO₄, decomposed at about 1000° C.), strontium sulfate (SrSO₄, decomposed at about 1130° C.), barium sulfate (BaSO₄, decomposed at about 1200° C.), ferrous sulfate (FeSO₄), cobalt sulfate (CoSO₄), nickel sulfate (NiSO₄), zinc sulfate (ZnSO₄), lead sulfate (PbSO₄), bismuth sulfate (Bi(SO₄)₃) and so on, and a compound containing at least one of nitrates of strontium nitrate (Sr(NO₃) 2), cesium nitrate (CsNO₃) and so on are used. These compounds are decomposed to generate gases by being heated. For example, by heating calcium carbonate, decomposition reaction (CaCO₃→CaO+CO₂↑) occurs and carbon dioxide (CO₂) is generated.

Alternatively, metal nitride containing at least one element of Ti, V, Cr, Mn, Fe, Co, Ni, Ga (gallium nitride is decomposed at about 900° C.), Zr, Mo (molybdenum nitride is decomposed at about 900° C.), Ta and W, metal sulfide containing at least one element of V, Cr, Mn, Fe, Co, Ni, Mo, Ta and W, and metal carbide such as TiC may be used. These compounds reacts, when heated, with components in the atmosphere and/or an adjacent layer, i.e., components contained in the substrate 101 and/or a layer to be peeled 104, which will be described later, to generate a gas. For example, in the case where a substrate containing oxide and a separation layer containing metal nitride are used, the separation layer reacts with the oxide and generates nitrogen (N₂).

As to which of these separation layer materials is selected, it is desired that the selection is made in consideration of interaction (diffusion or the like) with the substrate 101 or a layer to be peeled, which is formed at the next step S4, in addition to conditions of temperature or the like obtained depending on the relationship between an electromagnetic wave to be used and the electromagnetic wave absorbing layer 102.

As a method of forming the separation layer, a known method such as spin coating, sputtering and CVD (chemical vapor deposition) methods may be used.

Next, at step S4, a layer to be peeled 104 containing a material of a functional film as a target of manufacturing (functional material) is formed on the separation layer 103, as shown in FIG. 2D. The layer to be peeled 104 is formed by using a known method such as a sputtering method, a CVD method, a sol-gel method and an aerosol deposition (AD) method. Here, the AD method is a film forming method of generating an aerosol in which raw material powder is dispersed in a gas, injecting the aerosol from a nozzle toward a substrate to allow the raw material powder to collide with the under layer, and thereby, depositing the raw material on the substrate, and the method is also called “injection deposition method” or “gas deposition method”.

In the embodiment, specifically, the following materials are used as functional materials.

As a material of a functional film to be used for a memory element, Pb(Zr,Ti)O₃, SrBi₂ (Ta,Nb)₂O₉, Bi₄Ti₃O₁₂ and so on are cited.

As a material of a functional film to be used for a piezoelectric element such as an actuator, Pb(Zr,Ti)O₃, Pb(Mg_{1/3}Nb_{2/3})O₃, Pb(Zn_{1/3}Nb_{2/3})O₃, Pb(Ni_{1/3}Nb_{2/3})O₃ and so on, and solid solutions thereof are cited.

As a material of a functional film to be used for a pyroelectric element such as an infrared sensor, Pb(Zr,Ti)O₃, (Pb,La)(Zr,Ti)O₃ and so on are cited.

As a material of a functional film to be used for a passive component such as a capacitor, BaSrTiO₃, (Pb,La)(Zr,Ti)O₃ and so on are cited.

As a material of a functional film to be used for an optical element such as an optical switch, (Pb,La)(Zr,Ti)O₃, LiNbO₃ and so on are cited.

As a material of a functional film to be used for a superconducting element such as a superconducting quantum interference device (SQUID), YBa₂Cu₃O₇, Bi₂Sr₂Ca₂Cu₃O₁₀ and so on are cited. Here, SQUID refers to a highly sensitive magnetic sensor element utilizing superconductivity.

As a material of a functional film to be used for a photoelectric conversion element such as a solar cell, amorphous silicon and compound semiconductor are cited.

As a material of a functional film to be used for a micro magnetic element such as a magnetic head, PdPtMn, CoPtCr and so on are cited.

As a material of a functional film to be used for a semiconductor element such as a TFT, amorphous silicon and so on are cited.

A functional film containing structure according to the embodiment includes the substrate 101, the electromagnetic wave absorbing layer 102, the separation layer 103, and the layer to be peeled 104 formed at those steps S1 to S4.

Subsequently, heat treatment (post anneal) may be performed on the functional film containing structure at a temperature lower than the reaction temperature of the separation layer 103 according to need. This is because the function of the film can be improved by promoting the growth of crystal grain contained in the layer to be peeled (functional film) and improving crystallinity. For example, in order to improve the piezoelectric property of a PZT film, heat treatment may be performed at temperature of about 500° C. to 700° C.

Next, at step S5 in FIG. 1, a substrate for transfer 105 is provided on the layer to be peeled 104, as shown in FIG. 3A. In this regard, the substrate for transfer 105 may be fixed to the layer to be peeled 104 by using an adhesive agent 105a or the like. As the substrate for transfer 105, a desired substrate such as a synthetic resin substrate of epoxy or the like or glass substrate may be used. Further, electrodes and interconnections may be formed at the substrate for transfer 105 side in advance.

Next, at step S6, an electromagnetic wave is applied to the functional film containing structure 101 to 104 for allowing the electromagnetic wave absorbing layer 102 to generate heat. Thereby, as shown in FIG. 3B, the separation layer 103 adjacent to the electromagnetic wave absorbing layer 102 is heated, reaction such as decomposition occurs in the separation layer 103 and a gas is generated. As a result, the layer to be peeled 104 is peeled from the substrate 101. Thus, the layer to be peeled (functional film) 104 transferred to the substrate for transfer 105 as shown in FIG. 4 is obtained. Alternatively, the bonding strength between the layer to be peeled 104 and the substrate 101 or the electromagnetic wave absorbing layer 102 becomes lower because of generating the gas, and therefore, the layer to be peeled 104 can be dynamically and easily peeled form the substrate 101. In this case, the layer to be peeled 104 can be transferred by peeling the substrate for transfer 105 at the same time as the application of the electromagnetic wave or at the subsequent step.

For example, in the case where an infrared ray containing a component having an absorption wavelength of the electromagnetic wave absorbing layer 102 material is applied, molecules contained in the electromagnetic wave absorbing layer material absorb infrared energy to greatly vibrate and generate heat. Specifically, the case is cited where an infrared ray having a wavelength of about 2 μm to 10 μm is applied to carbon. In addition, in this case, the electromagnetic wave absorbing layer 102 can efficiently generate heat by using a substrate material that easily transmits the infrared ray and applying the infrared ray toward the electromagnetic wave absorbing layer 102 from the substrate 101 side as shown in FIG. 3B.

By the way, in the case of applying a microwave, the electromagnetic wave absorbing layer 102 generates heat according to the principle of microwave heating. Here, the absorption energy P of the microwave is expressed by the following equation (1).

P=(1/2)σ|E|²+πf∈₀∈ᵣ″|E|²+πfμ₀μᵣ″|H|² (1)

In equation (1), a represents an electric conductivity, f (Hz) represents a frequency of the microwave, ∈₀ represents a dielectric constant of vacuum, ∈ₜ″ represents a relative dielectric constant (complex), μ₀ represents a permeability of vacuum, μᵣ″ represents a relative permeability (complex), E represents an electric field intensity, and H represents a magnetic field intensity. Further, the first term of the equation (1) represents joule loss (resistance loss), the second term represents dielectric loss, and the third item represents magnetic hysteresis loss.

When an electromagnetic field is applied by applying a microwave to the electromagnetic wave absorbing layer 102, heat corresponding to energy expressed by the equation (1) is generated. As a result, the electromagnetic wave absorbing layer 102 generates heat. Therefore, in the case of using a microwave, in order to efficiently generate heat, it is desired that a material having a large relative dielectric constant (complex) ∈ᵣ″, a material having a large relative permeability (complex) μᵣ″, or a material having a large electric conductivity σ is used as the electromagnetic wave absorbing layer 102.

According to the principle of microwave heating, since the electromagnetic wave absorbing layer 102 is rapidly and uniformly heated to the interior thereof by being applied with the electromagnetic wave, reaction can be quickly caused in the separation layer 103 adjacent thereto, and thereby, the layer to be peeled 104 can be peeled from the substrate 101 in a short period of time or the bonding strength between them can be reduced. Further, while the microwave is applied, only the region applied with the microwave is locally heated, and therefore, the region is rapidly cooled when the application of microwave is stopped. As a result, the influence on other layers (e.g., the layer to be peeled 104 and the substrate for transfer 105) can be minimized. In the case of using a microwave, the microwave can reach the interior of the functional film containing structure without especially limiting an orientation of the microwave to be applied to the functional film containing structure.

As described above, according to the first embodiment of the present invention, by applying the electromagnetic wave to the electromagnetic wave absorbing layer to cause the layer to generate heat, the adjacent separation layer can be locally heated. Accordingly, even in the case where the separation layer itself has little sensitivity to an electromagnetic wave, reaction can be caused in the separation layer due to the heat. Therefore, a functional film formed by the film formation technology such as a sputtering method or an AD method through predetermined process temperature (e.g., about 350° C. or more) and an element containing such a functional film can be transferred to a desired substrate and utilized within a room at lower temperature (about 10° C. to about 100° C.). That is, the transfer can be performed to a resin substrate having relatively low heat tolerance, the range of choices of substrates can be expanded to a flexible substrate, for example, according to application.

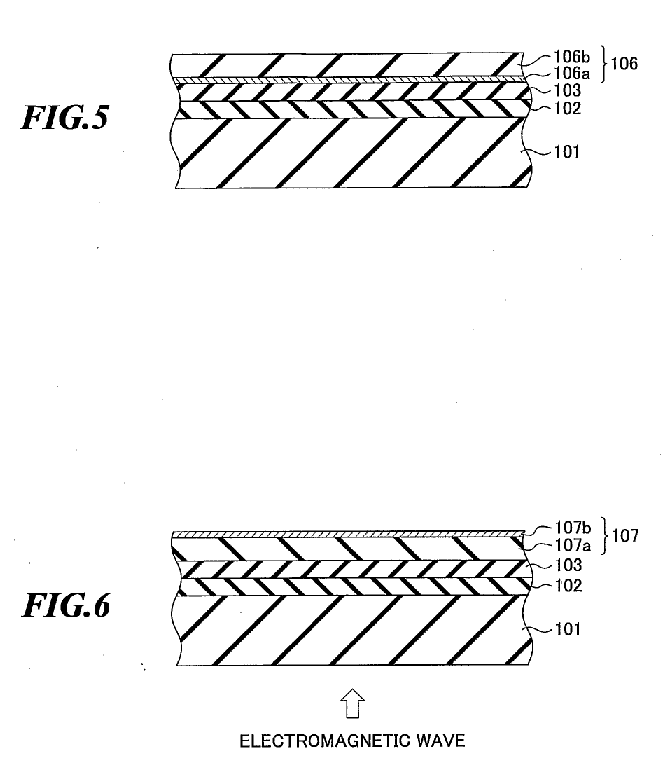

As a modified example of the functional film containing structure to be used in the manufacturing process of the functional film according to the embodiment, as shown in FIG. 5, a layer to be peeled 106 including an electrode layer 106a and a functional material layer 106b may be formed. Further, as another modified example of the functional film containing structure, as shown in FIG. 6, a layer to be peeled 107 including a functional material layer 107a and an electrode layer 107b may be formed. Furthermore, a layer to be peeled including electrode layers on both of upper and lower surfaces of the functional material layer may be used. The electrode layers 106a and 107b may be formed by a known method such as a sputtering method and an evaporation method.

Further, in the embodiment, the electromagnetic wave absorbing layer 102 has been formed on the substrate 101 in advance, and then, the separation layer 103 has been formed thereon. However, the arrangement is not limited to the above one as long as the heat generated in the electromagnetic wave absorbing layer 102 is conducted to the separation layer 103. For example, by forming the separation layer on the substrate and forming the electromagnetic wave absorbing layer thereon, the electromagnetic wave absorbing layer may be contained in the layer to be peeled. In this case, the electromagnetic wave absorbing layer may serve as the lower electrode of the functional material layer.

Furthermore, in the embodiment, at step S6, the layer to be peeled 104 has been transferred to the substrate for transfer 105 at the same time as being peeled from the substrate 101. However, only peeling of the layer to be peeled 104 may be performed without bonding the substrate for transfer 105 to the layer to be peeled 104. Thereby, a functional film, or a functional element containing a functional film and an electrode can be obtained singly.

### EXAMPLE 1

A carbon film having a thickness of about 0.2 μm is formed as an electromagnetic wave absorbing layer onto a quartz substrate by using the plasma CVD method. Then, a calcium carbonate thin film having a thickness of about 0.1 μm is formed as a separation layer by applying a calcium hydrogen carbonate solution on the carbon film by spin coating and drying it in an atmosphere at 200° C. Further, a lower electrode of platinum (Pt) is formed on the calcium carbonate thin film by evaporation, and a PZT (lead zirconium titanate) film having a thickness about 0.1 μm is formed by using the sputtering method thereon. At this time, the substrate is heated to a temperature of about 550° C. Furthermore, a Pt/PZT/Pt piezoelectric element is fabricated by forming an upper electrode of platinum on the PZT film by using a sputtering method.

Then, by using an infrared lamp, the carbon film as the electromagnetic wave absorbing layer is irradiated with an infrared ray having a wavelength of about 2 μm to about 10 μm. Thereby, the carbon film generates heat and the calcium carbonate thin film adjacent thereto is thermally decomposed to generate a gas. As a result, the Pt/PZT/Pt piezoelectric element is peeled from the quartz substrate.

### EXAMPLE 2

A calcium carbonate film having a thickness of about 0.1 μm is formed as a separation layer by applying a calcium hydrogen carbonate solution onto a quartz substrate by spin coating and drying it in an atmosphere at 200° C. Then, on the calcium carbonate thin film, an LaNiO₃ film having a thickness of about 0.3 μm serving as both an electromagnetic wave absorbing layer and a lower electrode is formed by using the sputtering method. On the LaNiO₃ film, a BST (barium strontium titanate) film having a thickness of about 0.3 μm is formed by using the sputtering method. At this time, the substrate is heated to a temperature of about 550° C. Furthermore, an upper electrode of platinum is formed on the BST film by using the sputtering method. Thereby, an LaNiO₃/BST/Pt thin film capacitor element is fabricated.

Then, microwave having a wavelength of about 28 GHz is applied to the thin film capacitor element. Thereby, the LaNiO₃ film generates heat, and the calcium carbonate film adjacent thereto is decomposed to generate a gas. As a result, the LaNiO₃/BST/Pt thin film capacitor element is peeled from the quartz substrate.

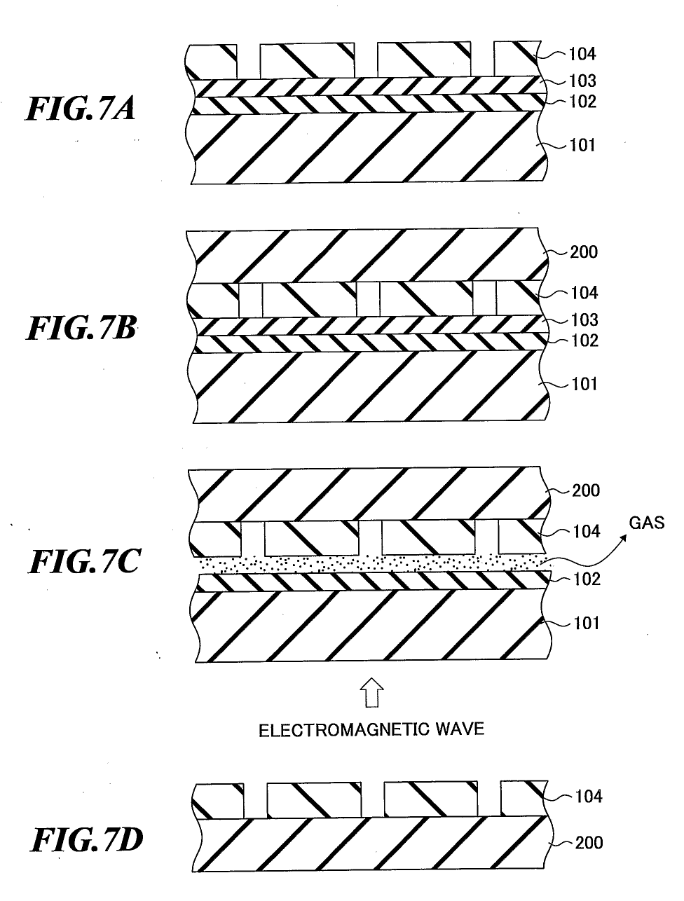

Next, a method of manufacturing a functional film according to the second embodiment will be explained by referring to FIGS. 2A to 2D and FIGS. 7A to 7D. The method of manufacturing a functional film according to the embodiment is a method of manufacturing a patterned functional film.

First, as shown in FIGS. 2A to 2D, a functional film containing structure 101 to 104 in which an electromagnetic wave absorbing layer 102, a separation layer 103, and a layer to be peeled 104 are formed on a substrate 101 is fabricated. The method of fabricating the function film containing structure 101 to 104 is the same as that has been explained in the first embodiment.

Then, as shown in FIG. 7A, a pattern is formed on the layer to be peeled 104 by dry etching. In this regard, as shown in FIG. 7A, etching may be performed only on the layer to be peeled 104, or etching may be performed to the separation layer 103 or the electromagnetic wave absorbing layer 102.

Further, as shown in FIG. 7B, a substrate for transfer 200 is provided on the layer to be peeled 104 on which the pattern has been formed. In this regard, the substrate for transfer 200 may be fixed to the layer to be peeled 104 by using an adhesive agent or the like. Further, as the substrate for transfer 200, a synthetic resin substrate, glass substrate or the like is used similarly to the first embodiment.

Furthermore, by applying an electromagnetic wave toward the function film containing structure 101 to 104, the electromagnetic wave absorbing layer 102 is caused to generate heat. Thereby, as shown in FIG. 7C, the separation layer 103 is heated, and reaction such as decomposition occurs in the separation layer 103 and a gas is generated. As a result, as shown in FIG. 7D, the patterned layer to be peeled (functional film) 104 is peeled from the substrate 101 and transferred to the substrate for transfer 200. Alternatively, the bonding strength between the layer to be peeled 104 and the substrate 101 or the electromagnetic wave absorbing layer 102 becomes lower because of generating the gas, and thereby, the layer to be peeled 104 can be transferred by peeling the substrate for transfer 200 at the same time as the application of the electromagnetic wave or at the subsequent step.

Thus, according to the second embodiment of the present invention, the pattern has been formed on the layer to be peeled of the functional film containing structure in advance, and therefore, the functional film or functional film element may be provided on the desired substrate to form a desired pattern. Therefore, an array in which plural functional elements are arranged can be fabricated easily.

In the above explained first and second embodiments of the present invention, heat treatment may be performed on the functional film containing structure in parallel to application of the electromagnetic wave to the electromagnetic wave absorbing layer 102. Thereby, the reaction in the separation layer 103 is promoted by the heat and an effect of improving the function of the functional film is expected. In this case, it is necessary to determine the heat treatment temperature in consideration of heat tolerance of the substrate for transfer 105 and the adhesive agent 105a (FIGS. 3A and 3B).

### INDUSTRIAL APPLICABILITY

The present invention can be applied to memory elements, piezoelectric elements, pyroelectric elements, passive elements such as capacitors, optical elements, superconducting elements, photoelectric conversion elements, micro magnetic elements and semiconductor elements containing functional materials such as dielectric materials, piezoelectric materials, pyroelectric materials, magnetic material and semiconductor materials, and instruments to which those elements are applied.

1. A functional film containing structure comprising:
a substrate;
an electromagnetic wave absorbing layer provided on said substrate and formed by using a material which absorbs an electromagnetic wave to generate heat;
a separation layer provided on said electromagnetic wave absorbing layer and formed by using an inorganic material which is decomposed to generate a gas by being heated; and
a layer to be peeled provided on said separation layer and containing a functional film formed by using a functional material;
wherein said layer to be peeled is peeled from said substrate or bonding strength between said layer to be peeled and said substrate becomes lower by applying the electromagnetic wave toward said electromagnetic wave absorbing layer.

2. The functional film containing structure according to claim 1, wherein said separation layer contains at least one of carbonate, sulfate and nitrate.

3. The functional film containing structure according to claim 2, wherein said separation layer contains at least one of magnesium carbonate (MgCO₃), calcium carbonate (CaCO₃), strontium carbonate (SrCO₃), barium carbonate (BaCO₃), lithium carbonate (LiCO₃), sodium carbonate (Na₂CO₃), potassium carbonate (K₂CO₃), magnesium sulfate (MgSO₄), calcium sulfate (CaSO₄), strontium sulfate (SrSO₄), barium sulfate (BaSO₄), iron sulfate (FeSO₄), cobalt sulfate (CoSO₄), nickel sulfate (NiSO₄), zinc sulfate (ZnSO₄), lead sulfate (PbSO₄), bismuth sulfate (Bi(SO₄)₃), strontium nitrate (Sr(NO₃)₂) and cesium nitrate (CsNO₃).

4. A functional film containing structure comprising:
a substrate;
an electromagnetic wave absorbing layer provided on said substrate and formed by using a material which absorbs an electromagnetic wave to generate heat;
a separation layer provided on said electromagnetic wave absorbing layer and formed by using an inorganic material which reacts with a component in an atmosphere and/or a component contained in an adjacent layer to generate a gas by being heated; and
a layer to be peeled provided on said separation layer and containing a functional film formed by using a functional material;
wherein said layer to be peeled is peeled from said substrate or bonding strength between said layer to be peeled and said substrate becomes lower by applying the electromagnetic wave toward said electromagnetic wave absorbing layer.

5. The functional film containing structure according to claim 4, wherein said separation layer contains at least one of metal nitride, metal carbide and metal sulfide.

6. The functional film containing structure according to claim 1, wherein said substrate includes one of a single crystal substrate, which includes one of an oxide single crystal substrate and a semiconductor single crystal substrate, and a ceramic substrate and a glass substrate.

7. The functional film containing structure according to claim 1, wherein said functional film contains at least one of a piezoelectric material, a pyroelectric material and a ferroelectric material.

8. The functional film containing structure according to claim 1, wherein said functional film contains a superconducting material.

9. The functional film containing structure according to claim 1, wherein said functional film contains a magnetic material.

10. The functional film containing structure according to claim 1, wherein said functional film contains a semiconductor material.

11. The functional film containing structure according to claim 1, wherein said electromagnetic wave absorbing layer contains at least one of carbon, ceramics and glass.

12. The functional film containing structure according to claim 1, wherein said layer to be peeled includes the functional film and at least one electrode layer formed on at least one of an upper surface and a lower surface of said functional film.

13. The functional film containing structure according to claim 1, wherein a predetermined pattern is formed in at least said layer to be peeled.

14. A method of manufacturing a functional film, said method comprising the steps of:
(a) forming an electromagnetic wave absorbing layer on a substrate by using a material which absorbs an electromagnetic wave to generate heat;
(b) forming a separation layer on said electromagnetic wave absorbing layer by using an inorganic material which is decomposed to generate a gas by being heated;
(c) forming a layer to be peeled containing a functional film, which is formed by using a functional material, on said separation layer; and
(d) applying the electromagnetic wave toward said electromagnetic wave absorbing layer so as to peel said layer to be peeled from said substrate or reduce bonding strength between said layer to be peeled and said substrate.

15. The method of manufacturing a functional film according to claim 14, wherein said separation layer contains at least one of carbonate, sulfate and nitrate.

16. The method of manufacturing a functional film according to claim 15, wherein said separation layer contains at least one of magnesium carbonate (MgCO₃), calcium carbonate (CaCO₃), strontium carbonate (SrCO₃), barium carbonate (BaCO₃), lithium carbonate (LiCO₃), sodium carbonate (Na₂CO₃), potassium carbonate (K₂CO₃), magnesium sulfate (MgSO₄), calcium sulfate (CaSO₄), strontium sulfate (SrSO₄), barium sulfate (BaSO₄), iron sulfate (FeSO₄), cobalt sulfate (CoSO₄), nickel sulfate (NiSO₄), zinc sulfate (ZnSO₄), lead sulfate (PbSO₄), bismuth sulfate (Bi(SO₄)₃), strontium nitrate (Sr(NO₃)₂) and cesium nitrate (CsNO₃).

17. A method of manufacturing a functional film, said method comprising the steps of:
(a) forming an electromagnetic wave absorbing layer on a substrate by using a material which absorbs an electromagnetic wave to generate heat;
(b) forming a separation layer on said electromagnetic wave absorbing layer by using an inorganic material which reacts with a component in an atmosphere and/or a component contained in an adjacent layer to generate a gas by being heated;
(c) forming a layer to be peeled containing a functional film, which is formed by using a functional material, on said separation layer; and
(d) applying the electromagnetic wave toward said electromagnetic wave absorbing layer so as to peel said layer to be peeled from said substrate or reduce bonding strength between said layer to be peeled and said substrate.

18. The method of manufacturing a functional film according to claim 17, wherein said separation layer contains at least one of metal nitride, metal carbide and metal sulfide.

19. The method of manufacturing a functional film according to claim 14, wherein said substrate includes one of a single crystal substrate, which includes one of an oxide single crystal substrate and a semiconductor single crystal substrate, and a ceramic substrate and a glass substrate.

20. The method of manufacturing a functional film according to claim 14, wherein said functional film contains at least one of a piezoelectric material, a pyroelectric material and a ferroelectric material.

21. The method of manufacturing a functional film according to claim 14, wherein said functional film contains a superconducting material.

22. The method of manufacturing a functional film according to claim 14, wherein said functional film contains a magnetic material.

23. The method of manufacturing a functional film according to claim 14, wherein said functional film contains a semiconductor material.

24. The method of manufacturing a functional film according to claim 14, wherein step (c) includes forming an electrode layer on said separation layer, and forming the functional film on said electrode layer.

25. The method of manufacturing a functional film according to claim 14, wherein step (c) includes forming an electrode layer on the functional film formed directly or indirectly on said separation layer.

26. The method of manufacturing a functional film according to claim 14, wherein said electromagnetic wave absorbing layer contains at least one of carbon, ceramics and glass.

27. The method of manufacturing a functional film according to claim 14, wherein step (d) includes applying a microwave toward said electromagnetic wave absorbing layer.

28. The method of manufacturing a functional film according to claim 14, wherein step (d) includes applying an infrared ray toward said electromagnetic wave absorbing layer.

29. The method of manufacturing a functional film according to claim 14, further comprising the step of:
(c′) providing a second substrate on said layer to be peeled prior to step (d);
wherein step (d) includes applying the electromagnetic wave toward said electromagnetic wave absorbing layer so as to transfer said layer to be peeled to said second substrate.

30. The method of manufacturing a functional film according to claim 29, wherein step (c′) includes fixing said second substrate to said layer to be peeled by using an adhesive agent.

31. The method of manufacturing a functional film according to claim 29, further comprising the step of:
forming a pattern at least in said layer to be peeled by etching prior to step (c′);
wherein step (d) includes applying the electromagnetic wave toward said electromagnetic wave absorbing layer so as to transfer said layer to be peeled formed with the pattern to said second substrate.
